(19) United States
(12) Patent Application Publication
(10) Pub. No.: US 2026/0302734 A1
(43) Pub. Date: Oct. 1, 2026

(54) SEMICONDUCTOR STACK AND OPTICAL SEMICONDUCTOR DEVICE

(71) Applicant: SUMITOMO ELECTRIC INDUSTRIES, LTD., Osaka (JP)

(72) Inventor: Kenshi TAKADA, Osaka (JP)

(73) Assignee: SUMITOMO ELECTRIC INDUSTRIES, LTD., Osaka (JP)

(21) Appl. No.: 19/483,268

(22) PCT Filed: May 9, 2024
(86) PCT No.: PCT/JP2024/017231

§ 371 Date: Nov. 11, 2025

(30) Foreign Application Priority Data
May 12, 2023 (JP) 2023-079312

(51) Int. Cl. H01S 5/343

(52) U.S. Cl. CPC H01S 5/3434

(57) ABSTRACT

A semiconductor stack includes a first p-type semiconductor layer formed of a III-V group compound semiconductor and having a p-type conductivity and a first n-type semiconductor layer formed of a III-V group compound semiconductor and having an n-type conductivity, the first n-type semiconductor layer being stacked on the first p-type semiconductor layer so as to be in contact with the first p-type semiconductor layer. The first p-type semiconductor layer contains carbon as an acceptor. In the first n-type semiconductor layer, carbon functions as a donor.

### TECHNICAL FIELD

The present disclosure relates to a semiconductor stack and an optical semiconductor device.

This application claims priority based on Japanese Patent Application No. 2023-079312 filed on May 12, 2023, and the entire contents of which are incorporated herein by reference.

### BACKGROUND ART

A semiconductor stack including a structure (pn junction) in which an n-type semiconductor layer having an n-type conductivity and a p-type semiconductor layer having a p-type conductivity are stacked in contact with each other may be used to manufacture various semiconductor devices. For example, a laser diode structure including a p-type semiconductor layer and an n-type semiconductor layer forming a tunnel junction has been proposed (Non-Patent Literature 1).

### CITATION LIST

### Non Patent Literature

Non-Patent Literature 1: M. Arzberger et al., “Low-resistivity p-side contacts for InP-based devices using buried InGaAs tunnel junction”, Electronics Letter 6th vol. 36, No. 1(2000 )

### SUMMARY OF INVENTION

A semiconductor stack according to the present disclosure includes a first p-type semiconductor layer formed of a III-V group compound semiconductor and having a p-type conductivity, and a first n-type semiconductor layer formed of a III-V group compound semiconductor and having an n-type conductivity, the first n-type semiconductor layer being stacked on the first p-type semiconductor layer so as to be in contact with the first p-type semiconductor layer. The first p-type semiconductor layer contains carbon as an acceptor. In the first n-type semiconductor layer, carbon functions as a donor.

### BRIEF DESCRIPTION OF THE DRAWINGS

FIG. 1 is a schematic cross-sectional view showing a structure of a semiconductor stack.

FIG. 2 is a schematic view showing a structure of a semiconductor laser.

FIG. 3 is a flowchart showing an outline of a method of manufacturing a semiconductor stack and a semiconductor laser.

### DETAILED DESCRIPTION

### Problems to be Solved by Present Disclosure

The n-type semiconductor layer includes donors (n-type impurities that generate electrons which are majority carriers). The p-type semiconductor layer includes acceptors (p-type impurities that generate holes which are majority carriers). At the pn junction between the n-type semiconductor layer and p-type semiconductor layer, donors from the n-type semiconductor layer diffuse into the p-type semiconductor layer. In addition, the acceptors of the p-type semiconductor layer are diffused from the p-type semiconductor layer to the n-type semiconductor layer. As described above, there is a problem that carrier concentration decreases in the p-type semiconductor layer and the n-type semiconductor layer due to interdiffusion of impurities, causing the resistance of the pn junction to increase.

Thus, it is an object of the present disclosure to provide a semiconductor stack and an optical semiconductor device that can reduce an increase in resistance due to interdiffusion of impurities between a p-type semiconductor layer and an n-type semiconductor layer.

### Advantageous Effects of Present Disclosure

According to the semiconductor stack, it is possible to reduce an increase in resistance due to interdiffusion of impurities between a p-type semiconductor layer and an n-type semiconductor layer.

### Description of Embodiments of Present Disclosure

First, embodiments of the present disclosure will be listed and described. A semiconductor stack of the present disclosure includes
(1) a first p-type semiconductor layer formed of a III-V group compound semiconductor and having a p-type conductivity, and a first n-type semiconductor layer formed of a III-V group compound semiconductor and having an n-type conductivity, the first n-type semiconductor layer being stacked on the first p-type semiconductor layer so as to be in contact with the first p-type semiconductor layer. The first p-type semiconductor layer contains carbon as an acceptor. In the first n-type semiconductor layer, carbon functions as a donor.

In the semiconductor stack of the present disclosure, carbon contained as an acceptor in the first p-type semiconductor layer functions as a donor in the first n-type semiconductor layer when diffused into the first n-type semiconductor layer. That is, the carbon diffused into the first n-type semiconductor layer generates electrons which are majority carriers in the first n-type semiconductor layer. Here, compared to holes, which are majority carriers in the first p-type semiconductor layer, electrons, which are majority carriers in the first n-type semiconductor layer, have higher mobility, resulting in a greater influence on the resistance at the pn junction. Thus, according to the semiconductor stack of the present disclosure, it is possible to reduce an increase in resistance due to interdiffusion of impurities between the first p-type semiconductor layer and the first n-type semiconductor layer.
(2) In the above (1), the first n-type semiconductor layer may contain silicon, tellurium, or sulfur as a donor. Silicon, tellurium, and sulfur are all suitable as donors included in the first n-type semiconductor layer.
(3) In the above (1), the first n-type semiconductor layer may contain carbon as a donor. With this configuration, when the carbon contained as the donor in the first n-type semiconductor layer is diffused into the first p-type semiconductor layer, the carbon functions as an acceptor in the first p-type semiconductor layer. Thus, an increase in the resistance due to the interdiffusion of impurities between the first p-type semiconductor layer and the first n-type semiconductor layer can be further reduced.
(4) In any one of the above (1) to (3), the first n-type semiconductor layer may be formed of In₁₋ₓGaₓAs_{y}P_{1-y} in which inequalities 0<x<0.3 and 0<y<1 are satisfied. In such a first n-type semiconductor layer, carbon functions as a donor. Thus, such a first n-type semiconductor layer is suitable as the first n-type semiconductor layer of the present disclosure.
(5) In any one of the above (1) to (4), the first n-type semiconductor layer may have a carrier concentration of 1×10¹⁸ cm⁻³ or higher. The first p-type semiconductor layer may have a carrier concentration of 1×10¹⁸ cm⁻³ or higher. As described above, in the pn junction formed by the semiconductor layers having a high carrier concentration, the influence of the interdiffusion of impurities on the resistance is large. Thus, in such a configuration, the effect of applying the semiconductor stack of the present disclosure is large.
(6) In any one of the above (1) to (4), the first n-type semiconductor layer may have a carrier concentration of 1×10¹⁹ cm⁻³ or higher. The first p-type semiconductor layer may have a carrier concentration of 1×10¹⁹ cm⁻³ or higher. The first n-type semiconductor layer may form a tunnel junction with the first p-type semiconductor layer. As described above, the semiconductor stack of the present disclosure is particularly suitable for use in a semiconductor stack including a tunnel junction that requires a first n-type semiconductor layer and a first p-type semiconductor layer with high carrier concentration.
(7) In the above (6), the semiconductor stack may further include a second n-type semiconductor layer formed of a III-V group compound semiconductor and having an n-type conductivity, an active layer formed of a III-V group compound semiconductor, a second p-type semiconductor layer formed of a III-V group compound semiconductor and having a p-type conductivity, and a third n-type semiconductor layer formed of a III-V group compound semiconductor and having an n-type conductivity. The second n-type semiconductor layer, the active layer, the second p-type semiconductor layer, the first p-type semiconductor layer, the first n-type semiconductor layer, and the third n-type semiconductor layer may be stacked in this order. Such a semiconductor stack can be used for manufacturing an optical semiconductor device.

An optical semiconductor device of the present disclosure includes
(8) the semiconductor stack according to the above (7), and an electrode disposed on or above the third n-type semiconductor layer. The optical semiconductor device of the present disclosure includes the semiconductor stack of the present disclosure, and thus can reduce an increase in the resistance due to the interdiffusion of impurities between the first p-type semiconductor layer and the first n-type semiconductor layer.
(9) In the above (8), each of the first n-type semiconductor layer and the first p-type semiconductor layer may have a compositional wavelength shorter than an emission wavelength of the optical semiconductor device. This configuration allows for the reduction of the absorption of light generated in the active layer by the first n-type semiconductor layer and the first p-type semiconductor layer. In the present application, the “compositional wavelength” of the semiconductor layer means the wavelength of light corresponding to the band gap energy determined by the composition of the semiconductor layer.

### Details of Embodiments of Present Disclosure

Next, embodiments of a semiconductor stack and an optical semiconductor device according to the present disclosure will be described below with reference to the drawings. In the drawings, the same or corresponding components are denoted by the same reference numerals, and description thereof will not be repeated.

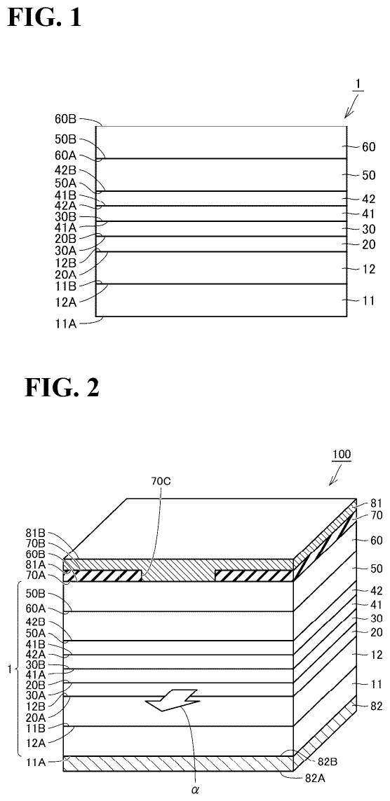

Referring to FIG. 1, a semiconductor stack 1 according to an embodiment of the present disclosure includes a substrate 11, a first n-type cladding layer 12, an active layer 20, a p-type cladding layer 30, a high-concentration p-type semiconductor layer 41, a high-concentration n-type semiconductor layer 42, a second n-type cladding layer 50, and an n-type contact layer 60 in this order.

The high-concentration p-type semiconductor layer 41 is a first p-type semiconductor layer formed of a III-V group compound semiconductor and having a p-type conductivity. The high-concentration n-type semiconductor layer 42 is a first n-type semiconductor layer formed of a III-V group compound semiconductor and having an n-type conductivity. The first n-type cladding layer 12 is a second n-type semiconductor layer having an n-type conductivity. The p-type cladding layer 30 is a second p-type semiconductor layer having a p-type conductivity. The second n-type cladding layer 50 and the n-type contact layer 60 are each a third n-type semiconductor layer having an n-type conductivity.

The substrate 11 is formed of a III-V group compound semiconductor. A diameter of the substrate 11 is 50 mm or more, and is, for example, 3 inches. The diameter of the substrate 11 may be 80 mm or more (for example, 4 inches), may be 100 mm or more (for example, 5 inches), and may be 130 mm or more (for example, 6 inches) for the purpose of improving productivity and yield of a semiconductor element such as an optical semiconductor device using the semiconductor stack 1. As the III-V group compound semiconductor that constitutes the substrate 11, for example, InP (n-InP) having an n-type conductivity can be adopted. As the n-type impurity contained in the substrate 11, for example, sulfur(S) or the like can be adopted. The substrate 11 has a higher impurity concentration than the first n-type cladding layer 12, and thus has a higher carrier concentration than the first n-type cladding layer 12. The n-type carrier concentration of the substrate 11 is, for example, 1×10¹⁷ cm⁻³ to 1×10¹⁹ cm⁻³. The substrate 11 has a first main surface 11A and a second main surface 11B.

Here, the carrier concentration means the concentration of carriers (holes or electrons) generated by impurities except for the impurities that are not activated among the impurities included in the semiconductor. The carrier concentration can be measured using, for example, ECV-pro, which is an electrochemical capacitance-voltage (ECV) measuring device manufactured by Nanometrics Incorporated.

The first n-type cladding layer 12 is disposed so as to be in contact with the second main surface 11B of the substrate 11. The first n-type cladding layer 12 is formed of a III-V group compound semiconductor. As the III-V group compound semiconductor that constitutes the first n-type cladding layer 12, for example, InP can be adopted. The first n-type cladding layer 12 has a first main surface 12A and a second main surface 12B. For example, InP (n-InP) having an n-type conductivity is adopted as the compound semiconductor that constitutes the first n-type cladding layer 12. As the n-type impurity contained in the first n-type cladding layer 12, for example, S or the like can be adopted.

An n-type carrier concentration of the first n-type cladding layer 12 is, for example, 1×10¹⁷ cm⁻³ to 1×10¹⁹ cm⁻³. The first n-type cladding layer 12 is in contact with the second main surface 11B of the substrate 11 at the first main surface 12A.

The active layer 20 is disposed so as to be in contact with the second main surface 12B of the first n-type cladding layer 12. The active layer 20 has a structure in which a plurality of element layers formed of III-V group compound semiconductors are stacked. More specifically, the active layer 20 may be a separate confinement heterostructure multiple quantum well (SCH-MQW) including an indium gallium arsenide (InGaAs) layer and an indium gallium arsenide phosphide (InGaAsP) layer, for example. The active layer 20 has a first main surface 20A and a second main surface 20B. The active layer 20 is in contact with the second main surface 12B of the first n-type cladding layer 12 at the first main surface 20A.

The p-type cladding layer 30 has a first main surface 30A and a second main surface 30B. The p-type cladding layer 30 is disposed so as to be in contact with the second main surface 20B of the active layer 20 at the first main surface 30A. The p-type cladding layer 30 is formed of a III-V group compound semiconductor. As the III-V group compound semiconductor that constitutes the p-type cladding layer 30, for example, InP can be adopted. For example, InP (p-InP) having a p-type conductivity is adopted as the compound semiconductor that constitutes the p-type cladding layer 30. As the p-type impurity contained in the p-type cladding layer 30, for example, Zn (zinc) or the like can be adopted. As a raw material of Zn, for example, DEZn (diethyl zinc), DMZn (dimethyl zinc), or the like can be adopted. A p-type carrier concentration of the p-type cladding layer 30 is, for example, 1×10¹⁷ cm⁻³ to 1×10¹⁹ cm⁻³.

The high-concentration p-type semiconductor layer 41 has a first main surface 41A and a second main surface 41B. The high-concentration p-type semiconductor layer 41 is disposed so as to be in contact with the second main surface 30B of the p-type cladding layer 30 at the first main surface 41A. The high-concentration p-type semiconductor layer 41 is formed of a III-V group compound semiconductor. The high-concentration p-type semiconductor layer 41 includes a p-type impurity at a high concentration, and thus the conductivity type is p-type. The high-concentration p-type semiconductor layer 41 contains carbon (C) as an acceptor (p-type impurity). That is, carbon is a dopant of the high-concentration p-type semiconductor layer 41, and the concentration of carbon is, for example, 1×10¹⁸ cm⁻³ or higher. As the III-V group compound semiconductor (III-V group compound semiconductor in which carbon functions as an acceptor) that constitutes the high-concentration p-type semiconductor layer 41, for example, InₓGa₁₋ₓAs can be adopted. In that case, the value of X can be 0.38 to 1. In addition, as the III-V group compound semiconductor that constitutes the high-concentration p-type semiconductor layer 41, AlₓIn_{y}Ga_{1-x-Y}As (aluminum indium gallium arsenide) may be adopted. In this case, the value of X can be 0 to 0.62, and the value of Y can be 0.38 to 1.

The high-concentration n-type semiconductor layer 42 has a first main surface 42A and a second main surface 42B. The high-concentration n-type semiconductor layer 42 is disposed so as to be in contact with the second main surface 41B of the high-concentration p-type semiconductor layer 41 at the first main surface 42A. The high-concentration n-type semiconductor layer 42 is formed of a III-V group compound semiconductor. The high-concentration n-type semiconductor layer 42 includes an n-type impurity at a high concentration, and thus the conductivity type is n-type. As the III-V group compound semiconductor that constitutes the high-concentration n-type semiconductor layer 42, In₁₋ₓGaₓAs_{y}P_{1-y} can be adopted. In this case, inequalities 0<x<0.3 and 0<y<1 are satisfied. In the present embodiment, the high-concentration n-type semiconductor layer 42 contains a high concentration of Si (silicon) as an n-type impurity that generates electrons, which are majority carriers. As the n-type impurity of the high-concentration n-type semiconductor layer 42, tellurium (Te), sulfur(S), or the like may be adopted instead of silicon (Si). The high-concentration n-type semiconductor layer 42 may include carbon that has diffused from the high-concentration p-type semiconductor layer 41. The carbon concentration of the high-concentration n-type semiconductor layer 42 is smaller than that of the high-concentration p-type semiconductor layer 41, and is at most 1×10¹⁹ cm⁻³, although it varies depending on the carbon concentration of the high-concentration p-type semiconductor layer 41. In the high-concentration n-type semiconductor layer 42 having the above configuration, carbon functions as a donor. That is, even when carbon, which is a dopant (acceptor) of the high-concentration p-type semiconductor layer 41, is diffused into the high-concentration n-type semiconductor layer 42, the carbon functions as a donor in the high-concentration n-type semiconductor layer 42. Thus, an effective carrier concentration is not lowered by the impurity diffusion, and an increase in resistance can be reduced.

In the present embodiment, a p-type carrier concentration of the high-concentration p-type semiconductor layer 41 is 1×10¹⁹ cm⁻³ or higher. An n-type carrier concentration of the high-concentration n-type semiconductor layer 42 is 1×10¹⁹ cm⁻³ or higher. The high-concentration p-type semiconductor layer 41 forms a tunnel junction with the high-concentration n-type semiconductor layer 42. That is, electrons in the valence band of the high-concentration p-type semiconductor layer 41 tunnel to the conduction band of the high-concentration n-type semiconductor layer 42. The p-type carrier concentration of the high-concentration p-type semiconductor layer 41 may be, for example, 1×10²⁰ cm⁻³ or less. The n-type carrier concentration of the high-concentration n-type semiconductor layer 42 may be, for example, 1×10²⁰ cm⁻³ or less.

The second n-type cladding layer 50 has a first main surface 50A and a second main surface 50B. The second n-type cladding layer 50 is disposed so as to be in contact with the second main surface 42B of the high-concentration n-type semiconductor layer 42 at the first main surface 50A. The second n-type cladding layer 50 is formed of a III-V group compound semiconductor. As the III-V group compound semiconductor that constitutes the second n-type cladding layer 50, for example, InP can be adopted. For example, InP (n-InP) having an n-type conductivity is adopted as the compound semiconductor that constitutes the second n-type cladding layer 50. As the n-type impurity contained in the second n-type cladding layer 50, for example, S or the like can be adopted. An n-type carrier concentration of the second n-type cladding layer 50 is, for example, 1×10¹⁷ cm⁻³ to 1×10¹⁹ cm⁻³.

The n-type contact layer 60 has a first main surface 60A and a second main surface 60B. The n-type contact layer 60 is disposed so as to be in contact with the second main surface 50B of the second n-type cladding layer 50 at the first main surface 60A. The n-type contact layer 60 is formed of a III-V group compound semiconductor. As the III-V group compound semiconductor that constitutes the n-type contact layer 60, for example, InP can be adopted. For example, InP (n-InP) having an n-type conductivity is adopted as the compound semiconductor that constitutes the n-type contact layer 60. As the n-type impurity contained in the n-type contact layer 60, for example, S or the like can be adopted. The n-type contact layer 60 has a higher impurity concentration than the second n-type cladding layer 50, and thus has a higher carrier concentration than the second n-type cladding layer 50. An n-type carrier concentration of the n-type contact layer 60 is, for example, 1×10¹⁸ cm⁻³ to 1×10²⁰ cm⁻³.

The semiconductor stack 1 of the present embodiment includes the high-concentration p-type semiconductor layer 41 and the high-concentration n-type semiconductor layer 42 that form a tunnel junction. This allows the second n-type cladding layer 50 and the n-type contact layer 60, which are n-type semiconductor layers, to constitute a region located on the side opposite to the active layer 20 when viewing from the high-concentration p-type semiconductor layer 41 and the high-concentration n-type semiconductor layer 42. The n-type semiconductor layer generally tends to have a smaller contact resistance with an electrode than the p-type semiconductor layer. In addition, the n-type semiconductor layer tends to have a lower light absorption than the p-type semiconductor layer. Thus, for example, by forming an electrode so as to be in contact with the n-type contact layer 60 of the semiconductor stack 1 of the present embodiment and fabricating a semiconductor laser that is an optical semiconductor element, a highly efficient semiconductor laser can be obtained.

Further, in the semiconductor stack 1 of the present embodiment, carbon contained as an acceptor in the high-concentration p-type semiconductor layer 41 functions as a donor in the high-concentration n-type semiconductor layer 42 when diffused into the high-concentration n-type semiconductor layer 42. That is, the carbon diffused into the high-concentration n-type semiconductor layer 42 generates electrons which are majority carriers in the high-concentration n-type semiconductor layer 42. Thus, according to the semiconductor stack 1 of the present embodiment, it is possible to reduce an increase in the resistance due to the interdiffusion of impurities between the high-concentration p-type semiconductor layer 41 and the high-concentration n-type semiconductor layer 42.

Next, a semiconductor laser, which is a semiconductor luminescent element, will be described as an example of an optical semiconductor device that can be fabricated using the semiconductor stack 1. Referring to FIG. 2, a semiconductor laser 100 according to the present embodiment is fabricated using the semiconductor stack 1 according to the present embodiment, and includes the substrate 11, the first n-type cladding layer 12, the active layer 20, the p-type cladding layer 30, the high-concentration p-type semiconductor layer 41, the high-concentration n-type semiconductor layer 42, the second n-type cladding layer 50, and the n-type contact layer 60.

The semiconductor laser 100 further includes an insulating film 70, a first electrode 81, and a second electrode 82. The insulating film 70 is disposed so as to be in contact with the second main surface 60B of the n-type contact layer 60. The insulating film 70 is formed of an insulator such as silicon nitride or silicon oxide. The insulating film 70 has a first main surface 70A and a second main surface 70B. An opening 70C penetrating the insulating film 70 in a thickness direction is formed in the insulating film 70.

The first electrode 81 is disposed so as to be in contact with the second main surface 70B of the insulating film 70. The first electrode 81 is formed of a conductor such as metal. More specifically, the first electrode 81 may be formed of a metal layer in which a titanium (Ti) layer, a platinum (Pt) layer, and a gold (Au) layer are stacked in this order, for example. The first electrode 81 fills the opening 70C formed in the insulating film 70. As a result, the first electrode 81 is in contact with the second main surface 60B of the n-type contact layer 60 exposed in the opening 70C. The first electrode 81 is in ohmic contact with the n-type contact layer 60.

The second electrode 82 is disposed so as to be in contact with the first main surface 11A of the substrate 11. The second electrode 82 is formed of a conductor such as metal. More specifically, the second electrode 82 may be formed of a metal layer in which a Ti layer, a Pt layer, and an Au layer are stacked in this order, for example. The second electrode 82 is in ohmic contact with the substrate 11. The semiconductor laser 100 is an edge-emitting laser diode having a Fabry-Perot structure.

When a voltage is applied between the first electrode 81 and the second electrode 82, current flows between the first electrode 81 and the second electrode 82. At this time, holes are injected into the active layer 20 from the first electrode 81, and electrons are injected into the active layer 20 from the second electrode 82. Then, the holes and the electrons are recombined in the active layer 20, and light is generated. The generated light is confined in the active layer 20 in a thickness direction thereof, the active layer 20 sandwiched between the first n-type cladding layer 12 and the p-type cladding layer 30. This light is repeatedly reflected between the end surfaces of the active layer 20. As a result, in-phase is amplified, and laser oscillation is achieved. Then, a laser beam is emitted along an arrow α.

The semiconductor laser 100 of the present embodiment includes the semiconductor stack 1 of the present embodiment. Thus, the semiconductor laser 100 is a highly efficient optical semiconductor device by including the high-concentration p-type semiconductor layer 41 and the high-concentration n-type semiconductor layer 42 forming the tunnel junction and reducing an increase in the resistance due to the interdiffusion of impurities between the high-concentration p-type semiconductor layer 41 and the high-concentration n-type semiconductor layer 42.

In the semiconductor laser 100 of the present embodiment, a compositional wavelength of each of the high-concentration p-type semiconductor layer 41 and the high-concentration n-type semiconductor layer 42 is preferably shorter than an emission wavelength of the semiconductor laser 100. This configuration allows for the reduction of the absorption of light generated in the active layer 20 by the high-concentration p-type semiconductor layer 41 and the high-concentration n-type semiconductor layer 42. As a result, the efficiency of the semiconductor laser 100 can be further improved.

Next, an overview of a method of manufacturing the semiconductor stack 1 and the semiconductor laser 100 according to the present embodiment will be described with reference to FIGS. 1 to 3.

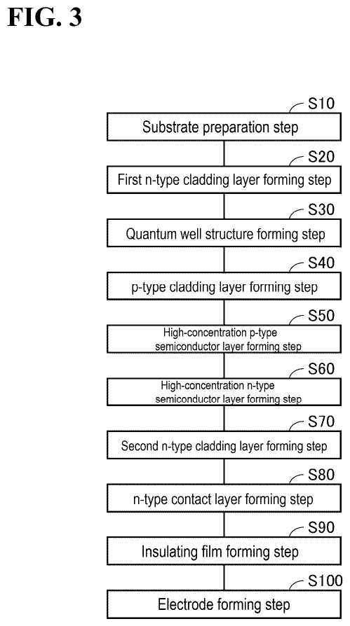

Referring to FIG. 3, in the method of manufacturing the semiconductor stack 1 and the semiconductor laser 100 according to the present embodiment, first, a substrate preparation step is performed as step S10. In the step S10, referring to FIG. 1, the substrate 11 formed of InP having an n-type conductivity is prepared, for example. More specifically, the substrate 11 formed of InP is obtained by slicing an ingot formed of InP.

After a surface of the substrate 11 is polished, the substrate 11 is subjected to a process such as cleaning to prepare the substrate 11 in which the flatness and cleanliness of the second main surface 11B are ensured.

Next, a first n-type cladding layer forming step is performed as step S20. In the step S20, the first n-type cladding layer 12 formed of, for example, n-InP, which is a III-V group compound semiconductor, is formed by a vapor phase growth method (for example, metal-organic chemical vapor deposition) so as to be in contact with the second main surface 11B of the substrate 11. In the formation of the first n-type cladding layer 12, for example, TMIn (trimethylindium) can be used as a raw material for In. As a raw material of P, for example, TBP (tertiary butyl phosphine) can be used.

Next, a quantum well structure forming step is performed as step S30. In the step S30, the active layer 20, which is an SCH-MQW including an InGaAs layer and an InGaAsP layer, for example, is formed by a vapor phase growth method so as to be in contact with the second main surface 12B of the first n-type cladding layer 12. In the formation of the active layer 20, for example, TMIn can be used as a raw material for In. As a raw material of Ga, for example, TEGa (triethyl gallium) can be used. As a raw material of As, TBAs (tertiary butyl arsine) or the like can be used. As the raw material of P, for example, TBP (tertiary butyl phosphine) can be used.

Next, a p-type cladding layer forming step is performed as step S40. In the step S40, the p-type cladding layer 30 is formed by a vapor phase growth method so as to be in contact with the second main surface 20B of the active layer 20. In the formation of the p-type cladding layer 30, for example, TMIn can be used as a raw material for In. As a raw material of P, for example, TBP can be used.

Next, a high-concentration p-type semiconductor layer forming step is performed as step S50. In the step S50, the high-concentration p-type semiconductor layer 41 formed of, for example, InₓGa₁₋ₓAs is formed so as to be in contact with the second main surface 30B of the p-type cladding layer 30. In the formation of the high-concentration p-type semiconductor layer 41, for example, TMIn can be used as a raw material for In. As a raw material of Ga, for example, TEGa can be used. As a raw material of As, TBAs or the like can be used. Further, as a raw material of carbon as a p-type impurity, for example, CBr₄ (carbon tetrabromide) can be used.

Next, a high-concentration n-type semiconductor layer formation step is performed as step S60. In the step S60, the high-concentration n-type semiconductor layer 42 formed of In₁₋ₓGaₓAs_{y}P_{1-y} (0<x<0.3 and 0<y<1) is formed so as to be in contact with the second main surface 41B of the high-concentration p-type semiconductor layer 41. In the formation of the high-concentration n-type semiconductor layer 42, for example, TMIn can be used as a raw material for In. As a raw material of Ga, for example, TEGa can be used. As a raw material of As, TBAs or the like can be used. As a raw material of P, for example, TBP (tertiary butyl phosphine) can be used. As a raw material of Si as an n-type impurity, for example, SiH₄ (silane), TeESi (tetraethylsilane), or the like can be used.

Next, a second n-type cladding layer forming step is performed as step S70. In the step S70, the second n-type cladding layer 50 is formed by a vapor phase growth method so as to be in contact with the second main surface 42B of the high-concentration n-type semiconductor layer 42. In the formation of the second n-type cladding layer 50, for example, TMIn can be used as a raw material for In. As a raw material of P, for example, TBP can be used.

Next, an n-type contact layer forming step is performed as step S80. In the step S80, the n-type contact layer 60 is formed by a vapor phase growth method so as to be in contact with the second main surface 50B of the second n-type cladding layer 50. In the formation of the n-type contact layer 60, for example, TMIn can be used as a raw material for In. As a raw material of P, for example, TBP can be used. The semiconductor stack 1 of the present embodiment is completed by performing the above steps S10 to S80.

Further, the semiconductor laser 100 can be fabricated using the semiconductor stack 1 by performing the following steps. Referring to FIG. 3, an insulating film forming step is performed as step S90 on the semiconductor stack 1 obtained by performing steps S10 to S80. In the step S90, referring to FIG. 2, the insulating film 70 is formed on the second main surface 60B of the n-type contact layer 60. Specifically, the insulating film 70 formed of an insulator such as silicon oxide or silicon nitride is formed by, for example, CVD (Chemical Vapor Deposition).

Next, an electrode forming step is performed as step S100. In the step S100, referring to FIG. 2, the first electrode 81 and the second electrode 82 are formed on the semiconductor stack 1 on which the insulating film 70 is formed. Specifically, referring to FIG. 2, a mask having an opening over a region where the opening 70C of the insulating film 70 is to be formed is formed on the insulating film 70. Then, the opening 70C is formed in the insulating film 70 using the mask. Thereafter, each of the first electrode 81 and the second electrode 82, each formed of an appropriate conductor, are formed by, for example, a vapor deposition method. The semiconductor laser 100 according to the present embodiment is completed by the above steps. Thereafter, it is separated into individual devices by dicing, for example.

In the method of manufacturing the semiconductor stack 1 according to the above embodiment, the case where each semiconductor layer is formed by a vapor phase growth method such as metal-organic chemical vapor deposition has been described, but the formation of each semiconductor layer may be achieved by, for example, a molecular beam epitaxy (MBE) method.

In the above embodiment, the case where the high-concentration n-type semiconductor layer 42 contains Si (silicon), Te (tellurium), or S (sulfur) as a donor has been described, but in another embodiment, C (carbon) may be adopted as a donor instead of these. That is, carbon may be a dopant of the high-concentration n-type semiconductor layer 42. By adopting this embodiment, carbon contained as a donor in the high-concentration n-type semiconductor layer 42 functions as an acceptor in the high-concentration p-type semiconductor layer 41 when diffused into the high-concentration p-type semiconductor layer 41. Thus, it is possible to further reduce an increase in the resistance due to the interdiffusion of impurities between the high-concentration p-type semiconductor layer 41 and the high-concentration n-type semiconductor layer 42. As described above, the semiconductor stack 1 of the present embodiment includes the high-concentration p-type semiconductor layer 41 and the high-concentration n-type semiconductor layer 42 forming the tunnel junction, and reduces an increase in the resistance due to the interdiffusion of impurities between the high-concentration p-type semiconductor layer 41 and the high-concentration n-type semiconductor layer 42. As a result, the semiconductor stack 1 of the present embodiment is a semiconductor stack that can contribute to high efficiency of a semiconductor device.

In the above embodiment, the case where the carrier concentration of the high-concentration p-type semiconductor layer 41 and the high-concentration n-type semiconductor layer 42 corresponding to the first p-type semiconductor layer and the first n-type semiconductor layer of the present disclosure, respectively, is 1×10¹⁹ cm⁻³ or higher has been described, but the carrier concentration of each of the first p-type semiconductor layer and the first n-type semiconductor layer is not limited to this range.

The carrier concentration of each of the first p-type semiconductor layer and the first n-type semiconductor layer may be, for example, 1×10¹⁶ cm⁻³ to 1×10¹⁹ cm⁻³. In the pn junction in which the carrier concentration of each of the first p-type semiconductor layer and the first n-type semiconductor layer is 1×10¹⁸ cm⁻³ or higher, the influence of the interdiffusion of impurities on the resistance is large, and thus, the effect of adopting the first p-type semiconductor layer and the first n-type semiconductor layer having the features of the present disclosure is large.

In the above embodiments, the laser diode (semiconductor laser) is exemplified as the optical semiconductor device of the present disclosure, and the semiconductor stack suitable for fabricating the laser diode is exemplified, but the optical semiconductor device of the present disclosure is not limited to the laser diode. The optical semiconductor device of the present disclosure may be, for example, a light emitting diode (LED) or a solar cell.

It should be understood that the embodiments disclosed herein are illustrative in all respects and are not restrictive in any aspect. The scope of the present invention is defined not by the above description but by the scope of the claims, and is intended to include all modifications within the meaning and scope equivalent to the scope of the claims.

### REFERENCE SIGNS LIST

1 semiconductor stack, 11 substrate, 11A first main surface, 11B second main surface, 12 first n-type cladding layer (second n-type semiconductor layer), 12A first main surface, 12B second main surface, 20 active layer, 20A first main surface, 20B second main surface, 30 p-type cladding layer (second p-type semiconductor layer), 30A first main surface, 30B second main surface, 41 high-concentration p-type semiconductor layer (first p-type semiconductor layer), 41A first main surface, 41B second main surface, 42 high-concentration n-type semiconductor layer (first n-type semiconductor layer), 42A first main surface, 42B second main surface, 50 second n-type cladding layer (third n-type semiconductor layer), 50A first main surface, 50B second main surface, 60 n-type contact layer (third n-type semiconductor layer), 60A first main surface, 60B second main surface, 70 insulating film, 70A first main surface, 70B second main surface, 70C opening, 81 first electrode (electrode), 82 second electrode, 100 semiconductor laser (optical semiconductor device), S10 to S100 steps, a arrow.

1. A semiconductor stack comprising:
a first p-type semiconductor layer formed of a III-V group compound semiconductor and having a p-type conductivity; and
a first n-type semiconductor layer formed of a III-V group compound semiconductor and having an n-type conductivity, the first n-type semiconductor layer being stacked on the first p-type semiconductor layer so as to be in contact with the first p-type semiconductor layer,
wherein the first p-type semiconductor layer contains carbon as an acceptor, and
in the first n-type semiconductor layer, carbon functions as a donor.

2. The semiconductor stack according to claim 1,
wherein the first n-type semiconductor layer contains silicon, tellurium, or sulfur as a donor.

3. The semiconductor stack according to claim 1,
wherein the first n-type semiconductor layer contains carbon as a donor.

4. The semiconductor stack according to claim 1,
wherein the first n-type semiconductor layer is formed of In₁₋ₓGaₓAs_{y}P_{1-y} in which inequalities 0<x<0.3 and 0<y<1 are satisfied.

5. The semiconductor stack according to claim 1,
wherein the first n-type semiconductor layer has a carrier concentration of 1×10¹⁸ cm⁻³ or higher, and
the first p-type semiconductor layer has a carrier concentration of 1×10¹⁸ cm⁻³ or higher.

6. The semiconductor stack according to claim 1,
wherein the first n-type semiconductor layer has a carrier concentration of 1×10¹⁹ cm⁻³ or higher,
the first p-type semiconductor layer has a carrier concentration of 1×10¹⁹ cm⁻³ or higher, and
the first n-type semiconductor layer forms a tunnel junction with the first p-type semiconductor layer.

7. The semiconductor stack according to claim 6, further comprising:
a second n-type semiconductor layer formed of a III-V group compound semiconductor and having an n-type conductivity;
an active layer formed of a III-V group compound semiconductor;
a second p-type semiconductor layer formed of a III-V group compound semiconductor and having a p-type conductivity; and
a third n-type semiconductor layer formed of a III-V group compound semiconductor and having an n-type conductivity,
wherein the second n-type semiconductor layer, the active layer, the second p-type semiconductor layer, the first p-type semiconductor layer, the first n-type semiconductor layer, and the third n-type semiconductor layer are stacked in this order.

8. An optical semiconductor device comprising:
the semiconductor stack according to claim 7; and
an electrode disposed on or above the third n-type semiconductor layer.

9. The optical semiconductor device according to claim 8,
wherein each of the first n-type semiconductor layer and the first p-type semiconductor layer has a compositional wavelength shorter than an emission wavelength of the optical semiconductor device.

10. A semiconductor stack comprising:
a first p-type semiconductor layer formed of a III-V group compound semiconductor and having a p-type conductivity; and
a first n-type semiconductor layer formed of a III-V group compound semiconductor and having an n-type conductivity, the first n-type semiconductor layer being stacked on the first p-type semiconductor layer so as to be in contact with the first p-type semiconductor layer,
wherein the first p-type semiconductor layer contains carbon as an acceptor, and
the first n-type semiconductor layer is formed of In₁₋ₓGaₓAs_{y}P_{1-y} in which inequalities 0<x<0.3 and 0<y<1 are satisfied, and contains carbon.

11. The semiconductor stack according to claim 1,
wherein the first n-type semiconductor layer contains carbon as a donor for generating carriers at a concentration of 1×10¹⁸ cm⁻³ or higher.
